(19) United States
(12) Patent Application Publication
(10) Pub. No.: US 2011/0195553 A1
(43) Pub. Date: Aug. 11, 2011

(54) METHOD OF FABRICATING SEMICONDUCTOR DEVICE

(76) Inventors: Chun-Yu Chou, Tainan County (TW); Chien-Liang Tung, Tainan County (TW); Chi-Wei Lin, Tainan County (TW)

(21) Appl. No.: 12/701,623

(22) Filed: Feb. 8, 2010

(51) Int. Cl. H01L 21/336

(52) U.S. Cl. 438/289; 257/E21.443

(57) ABSTRACT

A method of fabricating a semiconductor device is provided. The method comprises: forming a first layer; forming a P-well on the first layer; forming an isolation region in the P-well; performing an extra implantation on a surface between the P-well and the first layer; and forming a source/drain region. The method of the present invention can solve the punch through problem of the conventional iso-NMOS transistor without increasing cost.

### BACKGROUND OF THE INVENTION

1. Field of the Invention

The present invention relates to a method of fabricating a semiconductor device, and more particularly, to a method of fabricating a semiconductor device which is capable of avoiding punch through issue.

2. Description of the Prior Art

Please refer to FIG. 1. FIG. 1 shows a schematic sectional view of a conventional insulated type NMOS (iso-NMOS) transistor 100. As shown in FIG. 1, the iso-NMOS transistor 100 is fabricated by the following steps: forming a first layer 102; forming a P-well 104 on the first layer 102; forming isolation regions 106 in the P-well 104; forming a resistive impurity layer (not shown); forming a gate insulation layer (not shown); forming a gate conductive layer (not shown); forming offset regions 108; and forming a source/drain region (not shown). The first layer 102 can be a deep N-well, an epitaxy layer, or an N-barrier layer.

In general, the offset regions 108 are coupled to VCC, and the P-well 104 is coupled to ground (i.e. 0V). In this way, the iso-NMOS transistor 100 has a serious punch through issue between the first layer 102 (i.e. the deep N-well, the epitaxy layer, or the N-barrier layer) and the offset regions 108, and thus the iso-NMOS transistor 100 can not operate normally due to leakage.

### SUMMARY OF THE INVENTION

It is therefore one of the objectives of the present invention to provide a method of fabricating a semiconductor device which is capable of avoiding punch through issue, so as to solve the above problem.

According to an embodiment of the present invention, a method of fabricating a semiconductor device is disclosed. The method comprises: forming a first layer; forming a P-well on the first layer; forming an isolation region in the P-well; performing an extra implantation on a surface between the P-well and the first layer; and forming a source/drain region.

Briefly summarized, the method of the present invention can solve the punch through problem.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a schematic sectional view of a conventional iso-NMOS transistor.

FIG. 2 to FIG. 6 show schematic sectional views illustrating steps of a method of fabricating a semiconductor device according to an embodiment of the present invention.

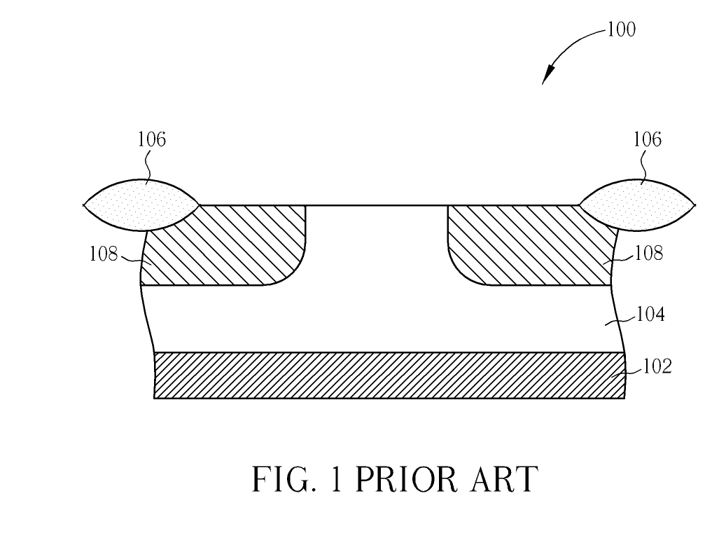

### DETAILED DESCRIPTION

Certain terms are used throughout the following description and claims to refer to particular components. As one skilled in the art will appreciate, hardware manufacturers may refer to a component by different names. This document does not intend to distinguish between components that differ in name but in function. In the following discussion and in the claims, the terms “include”, “including”, “comprise”, and “comprising” are used in an open-ended fashion, and thus should be interpreted to mean “including, but not limited to . . . ”.

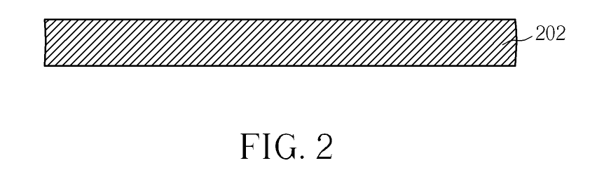

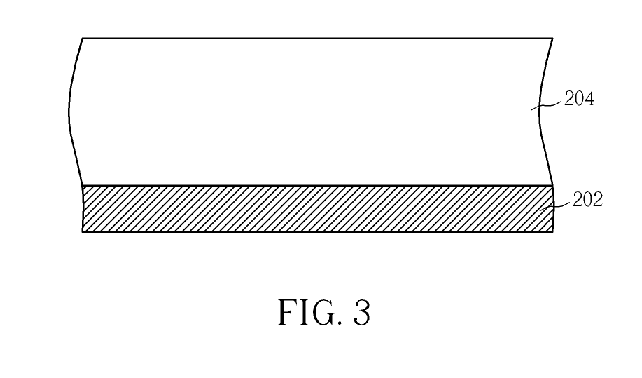

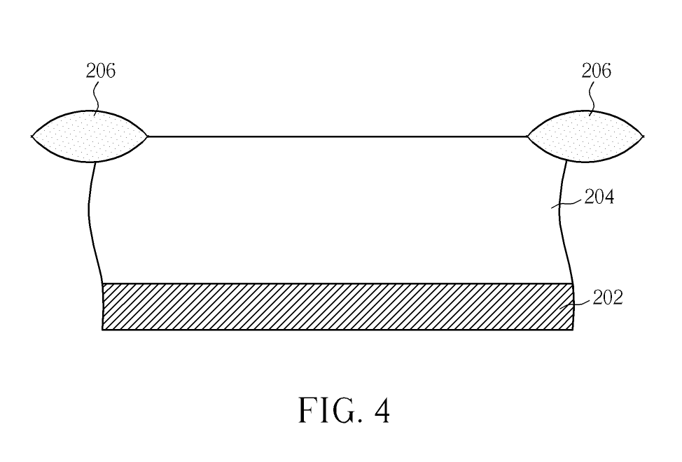

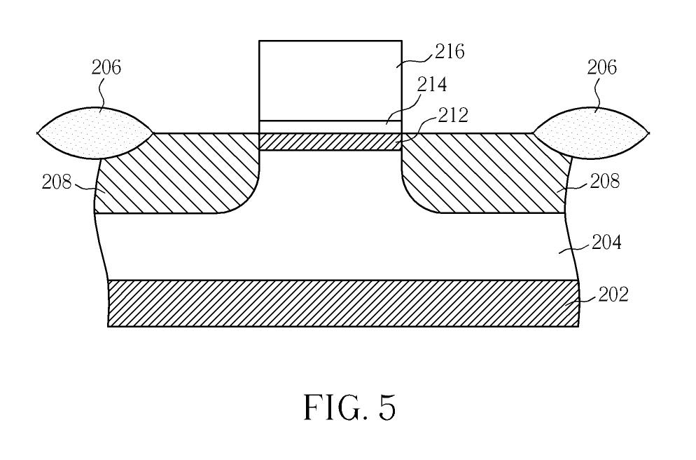

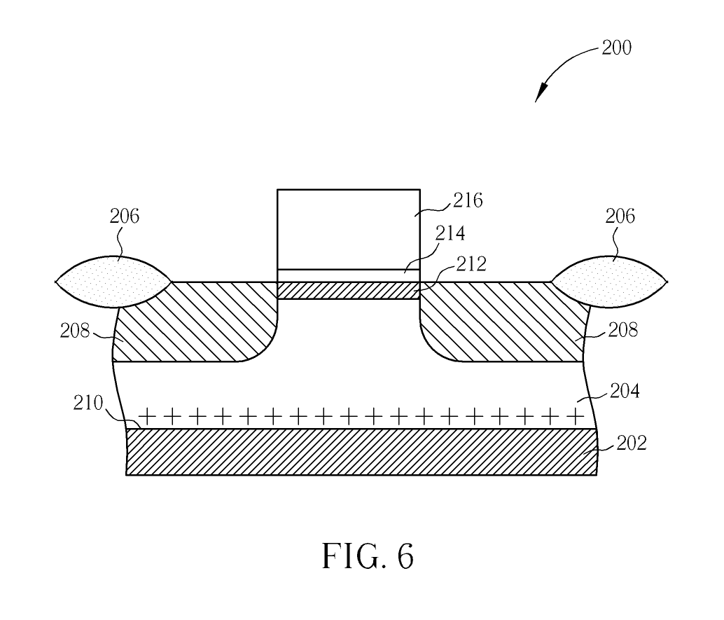

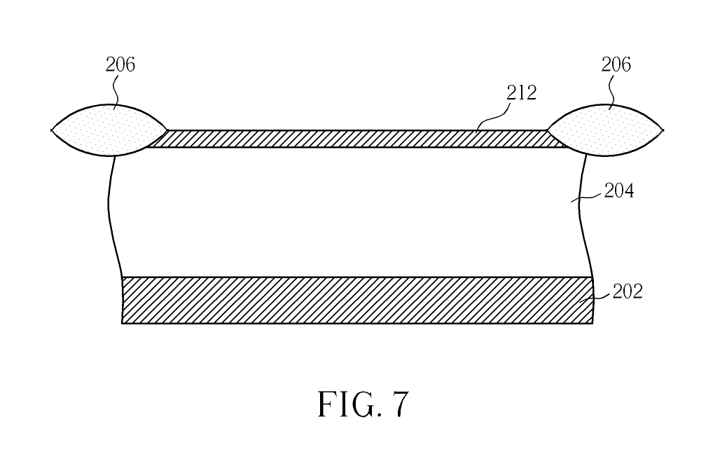

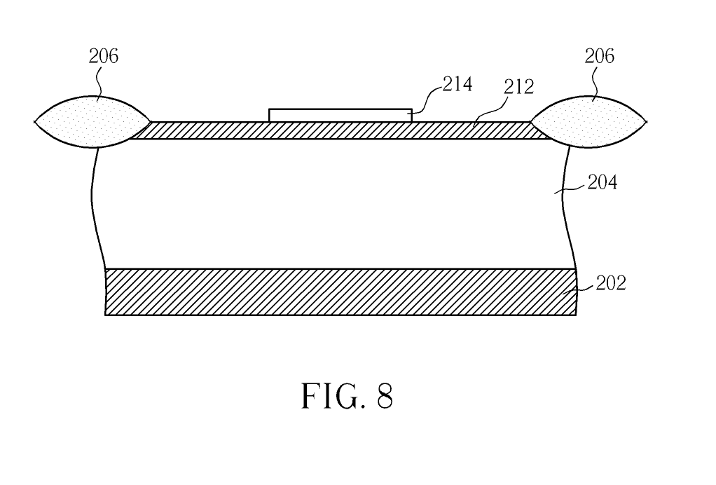

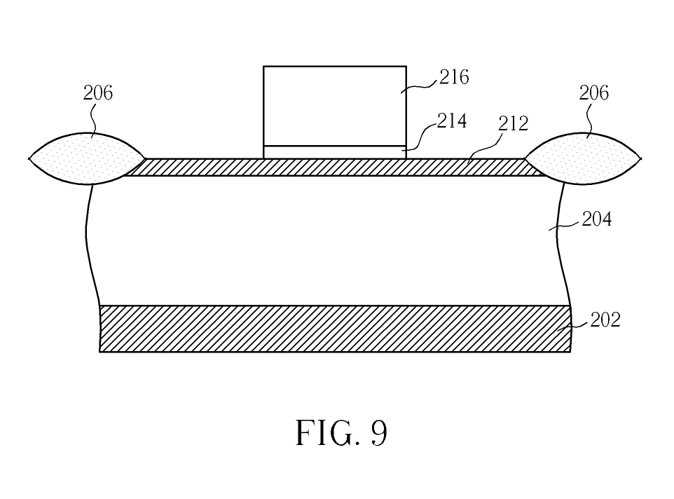

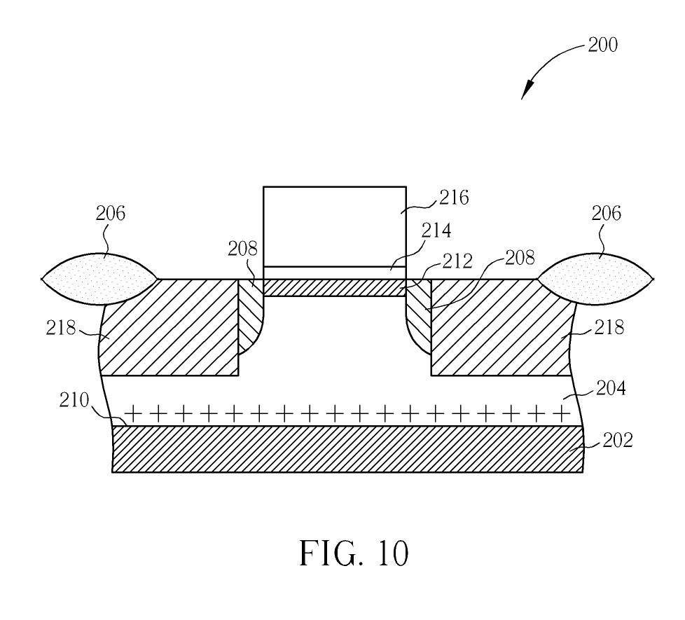

Please refer to FIG. 2 to FIG. 6. FIG. 2 to FIG. 6 show schematic sectional views illustrating steps of a method of fabricating a semiconductor device 200 according to an embodiment of the present invention. The method comprises: forming a first layer 202 (As shown in FIG. 2); forming a P-well 204 on the first layer 202 (As shown in FIG. 3); forming isolation regions 206 in the P-well 204 (As shown in FIG. 4); forming a resistive impurity layer (not shown); forming a gate insulation layer (not shown); forming a gate conductive layer (not shown); forming offset regions 208 (As shown in FIG. 5); performing an extra implantation on a surface 210 between the P-well 204 and the first layer 202; and forming a source/drain region (not shown). The first layer 202 can be a deep N-well, an epitaxy layer, or an N-barrier layer. The isolation regions 206 can be formed by a local oxidation silicon (LOCOS) process. The semiconductor device 200 is an insulated type NMOS transistor (iso-NMOS) transistor.

The extra implantation is a P-type implantation of the embodiment of the present invention. The extra implantation has light concentration by comparison to the P-well. For example, the extra implantation can be only about 10%-20% concentration of the P-well 204. The depth of the extra implantation position can be controlled by implant energy. Thus, the method of the present invention can solve the punch through problem by implanting the light concentration extra implantation on the surface 210 between the P-well 204 and the first layer 202. The step of performing the extra implantation can be performed by utilizing a mask that is utilized for forming the P-well. Thus, the method of the present invention does not need additional mask. Further, the device characteristic of the insulated type NMOS transistor (iso-NMOS) before extra implantation can be kept as well because of the deeply and lightly extra implantation.

Please note that the above embodiment is only for an illustrative purpose and is not meant to be a limitation of the present invention. For example, the step of performing the extra implantation can be before the step of forming the resistive impurity layer; or the step of performing the extra implantation can be after the step of forming the resistive impurity layer and before the step of forming the gate insulation layer; or the step of performing the extra implantation can be after the step of forming the gate insulation layer and before the step of forming the gate conductive layer; or the step of performing the extra implantation can be after the step of forming the gate conductive layer and before the step of forming the offset regions 208.

Briefly summarized, the method of the present invention can solve the punch through problem of the conventional iso-NMOS transistor without increasing cost.

Those skilled in the art will readily observe that numerous modifications and alterations of the device and method may be made while retaining the teachings of the invention.

1. A method of fabricating a semiconductor device, comprising:
forming a first layer;
forming a P-well on the first layer;
forming an isolation region in the P-well;
performing an extra implantation on a surface between the P-well and the first layer; and
forming a source/drain region;
wherein the first layer is a deep N-well, and the extra implantation is a P-type implantation that prevents punch through between the source/drain region and the first layer.

2. The method of claim 1, wherein:
the step of forming the P-well comprises:
utilizing a mask to for the P-well on the first layer; and
the step of performing the extra implantation comprises:
utilizing the mask to perform the extra implantation on the surface between the P-well and the first layer.

3. The method of claim 1, further comprising:
forming at least one of a resistive impurity layer, a gate insulation layer, a gate conductive layer, and an offset region after forming the isolation region and before forming the source/drain region.

4. The method of claim 3, wherein the step of forming at least one of the resistive impurity layer, the gate insulation layer, the gate conductive layer, and the offset region comprises:
forming the resistive impurity layer;
forming the gate insulation layer;
forming the gate conductive layer; and
forming the offset region.

5. The method of claim 4, wherein the step of forming the resistive impurity layer is before or after the step of performing the extra implantation.

6. The method of claim 4, wherein the step of forming the gate insulation layer is before or after the step of performing the extra implantation.

7. The method of claim 4, wherein the step of forming the gate conductive layer is before or after the step of performing the extra implantation.

8. The method of claim 4, wherein the step of forming the offset region is before or after performing the extra implantation.

9-11. (canceled)

12. The method of claim 1, wherein the isolation region is formed by a local oxidation silicon (LOCOS) process.

13. The method of claim 1, wherein the semiconductor device is an insulated type NMOS (iso-NMOS) transistor.

14. The method of claim 1, wherein the extra implantation is a P-type implantation with light concentration by comparison to the P-well.

15. The method of claim 14, wherein the extra implantation can be only about 10%˜20% concentration of the P-well.
